(19) United States
(12) Patent Application Publication
(10) Pub. No.: US 2016/0061668 A1
(43) Pub. Date: Mar. 3, 2016

(54) TEMPERATURE DISTRIBUTION PREDICTION METHOD AND AIR CONDITIONING MANAGEMENT SYSTEM

(71) Applicant: FUJITSU LIMITED, Kawasaki-shi (JP)

(72) Inventors: Takeo Kasajima, Machida (JP); Masatoshi OGAWA, Isehara (JP); Minoru Ishinabe, Atsugi (JP); Kazushi Uno, Atsugi (JP); Hiroyuki FUKUDA, Yokohama (JP); Masao KONDO, Sagamihara (JP); Takeshi Hatanaka, Meguro (JP); Masayuki Fujita, Meguro (JP)

(73) Assignee: FUJITSU LIMITED, Kawasaki (JP)

(21) Appl. No.: 14/819,738

(22) Filed: Aug. 6, 2015

(30) Foreign Application Priority Data
Sep. 3, 2014 (JP) 2014-179395

(51) Int. Cl. G01K 13/02; H05K 7/20

(52) U.S. Cl. CPC G01K 13/02; H05K 7/20745; H05K 7/20836; G01K 2013/024

(57) ABSTRACT

A temperature distribution prediction method of predicting a predetermined temperature distribution in an air conditioning system, the air conditioning system including an air conditioner for supplying temperature-adjusted air into a room where racks in which electronic apparatuses are accommodated are installed; and air blowers for transferring the air supplied from the air conditioner to an intake side of the racks, the method includes: measuring the temperature distribution for actual conditions varying the operating situations of the air blowers; and predicting the temperature distribution for conditions of non-measurement for the air blowers based on the measured values.

### CROSS-REFERENCE TO RELATED APPLICATION

This application is based upon and claims the benefit of priority of the prior Japanese Patent Application No. 2014-179395, filed on Sep. 3, 2014, the entire contents of which are incorporated herein by reference.

### FIELD

The embodiments discussed herein are related to a temperature distribution prediction method and an air conditioning management system.

### BACKGROUND

In recent years, with the advent of advanced information-oriented society, a large amount of data are being handled by a number of computers (computing devices) which are installed in the same room for a collective management. A data center is installed as a facility for collectively managing data.

In a data center, a number of racks (sever racks) are installed in the computer room and a plurality of computers is accommodated in each of the racks. Works are organically allocated to these computers for an efficient processing of a bulk of works.

A large amount of heat is normally generated from the computers as the computers process the work. Therefore, it is necessary to cool the computers in order to avoid a trouble, a malfunction and a deteriorated processing capacity of the computers.

The data center room is typically separated into an apparatus installation region where the racks are installed, and a free access floor (underfloor space) formed below the floor of the apparatus installation region to arrange the power cables and communication cables. Low temperature air (hereinafter referred to as cold air) is supplied from an air conditioner into the free access floor and the low temperature air is sent to the apparatus installation region via the grills (vent holes) installed in the floor of the apparatus installation region.

A number of racks are lined up side by side in each row in the apparatus installation region. In general, a rack is configured to cool the computers by introducing cold air from the front side of the rack and discharge the air with an increased temperature (hot air) from the rear side of the rack. Hereinafter, the front side of the rack is called an intake side and the rear side of the rack is called an exhaust side.

From the viewpoint of an energy saving and the prevention of a global warming, it is required that the power consumption in the data center to be reduced. In the data center, much power is consumed to cool the computers, and an efficient cooling is being attempted by studying the arrangement of the racks, along with power saving of the air conditioner. For example, in a general data center, a number of racks are lined up in rows, racks in adjacent rows are arranged side by side in such a manner that intake sides or exhaust sides face with each other, and the grills are arranged in a floor of the intake sides.

In this way, by separating a region into which the cold air is supplied via the grills from a region into which the hot air is discharged from the racks, an attempt is made to improve the cooling efficiency. The region of a rack intake side into which the cold air is supplied is called a cold aisle, and the region of a rack exhaust side from which the hot air is discharged is called a hot aisle.

However, when the hot air turns around from the hot aisle into the cold aisle, the temperature of an area may be increased locally to generate a hot spot (a locally hot portion), which may make the apparatus operation to be unstable.

This problem may be avoided by lowering the set temperature of the air conditioner in order to prevent the hot spot from being generated even when the exhaust air turns around into the cold aisle or by increasing the amount of blow-out of the air from the air conditioner to prevent the exhaust air from turning around into the cold aisle.

Document 4 discloses a technique for precisely detecting the temperature of measurement points set at intervals of 10 cm to several 10 cm along the longitudinal direction of an optical fiber. By using this technique, when the temperature of a plurality of sites in the cold aisle of the racks is measured and a hot spot is detected, the hot spot may be alleviated by lowering the set temperature of the air conditioner or increasing the amount of blow-out of air from the air conditioner. However, other regions than the hot spot may be excessively cooled resulting in an unnecessary increase of air conditioning energy.

In this way, any method where the setting of the air conditioner for cooling is changed to cool the entire area in order to deal with the hot spot is likely to excessively cool the regions other than the hot spot, which may increase the necessary power for air conditioning wasting energy.

It may be considered that these hot spots may be alleviated by installing underfloor fans in the free access floor and constructing a system for supplying cold air locally. For example, when underfloor fans are installed below the grills of the intake sides of the respective racks, the amount of air supply may be minutely adjusted depending on the temperature of the intake sides of the racks. This facilitates the local cooling to alleviate the hot spots, without the need to lower the set temperature of the air conditioner and without wasteful power consumption.

In this case, however, the installation cost may increase because the same number of underfloor fans is necessary as the number of racks. In addition, more underfloor fans require more power consumption. Therefore, there is a desire to provide an air conditioning management system in which the computers or other electronic apparatuses in the racks are efficiently cooled with less number of underfloor fans than the racks.

Here, considering the temperature change in each rack, the intake temperature of the racks near the underfloor fans is decreased by the operation of the underfloor fans, whereas the intake temperature of the racks at the further side from the underfloor fans is increased. This is because the total amount of cold air supplied from the air conditioner is constant and, accordingly, the cold air in a certain region is decreased when the cold air in a specific region is increased by the operation of the underfloor fans.

In addition, in order to facilitate more precise control, fans taking a plurality of operating levels (e.g., “OFF,” “Weak,” “Middle” and “Strong”) are being used. However, since such a trade-off relationship varies depending on the fan operation levels, it is necessary to appropriately select the fan operation levels so that the rack intake side may have a desirable temperature distribution. In addition, since a temperature distribution in the data center changes due to the variation of the amount of heat generated in apparatuses such as servers, the fan operation levels has to be accordingly changed from time to time. However, in general, the conditions of airflow in the data center are too complicated to understand the above-described trade-off relationship in advance. Accordingly, in order to select a proper fan operating level, a proper condition has to be found by changing the fan operating level to some extent comprehensively.

For example, when the number of underfloor fans each taking K operating levels is N, K^{N} conditions may be employed. For example, if two underfloor fans each taking four operating levels (e.g., “OFF,” “Weak,” “Middle” and “Strong”) are installed, 16 (=4²) conditions are taken. If three underfloor fans each taking four operating levels are installed, 64 (=4³) conditions are taken.

Further, it takes about 5 minutes until the respective conditions are stabilized after being changed. Therefore, since it is not realistic to measure for all of the conditions, it has been difficult to set proper fan operating conditions.

As described above, if a plurality of underfloor fans is present each having a number of operating levels to be taken, it is realistically difficult to measure and determine the entire conditions for the operating state that may effectively lower the rack intake side temperature.

The following are reference documents.

[Document 1] Japanese Laid-Open Patent Publication No. 2000-283526,

[Document 2] Japanese Laid-Open Patent Publication No. 2008-075973,

[Document 3] Japanese Laid-Open Patent Publication No. 2002-195625, and

[Document 4] International Publication Pamphlet No. WO2010/125712.

### SUMMARY

According to an aspect of the invention, a temperature distribution prediction method of predicting a predetermined temperature distribution in an air conditioning system, the air conditioning system including an air conditioner for supplying temperature-adjusted air into a room where racks in which electronic apparatuses are accommodated are installed; and air blowers for transferring the air supplied from the air conditioner to an intake side of the racks, the method includes: measuring the temperature distribution for actual conditions varying the operating situations of the air blowers; and predicting the temperature distribution for conditions of non-measurement for the air blowers based on the measured values.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a view illustrating an exemplary configuration of an indoor air conditioning management system where the racks are installed accommodating electronic devices;

FIG. 2 is a view illustrating an example of arrangement of two rows of racks;

FIGS. 3A and 3B are views illustrating an air conditioning management system in which two underfloor fans are installed in a free access floor in a data center room in which two rows of racks are installed, FIG. 3A illustrating the configuration and arrangement of the system and FIG. 3B illustrating a temperature change according to the operation of the underfloor fans;

FIG. 4 is a view illustrating a relationship between blow-out set temperature and power consumption of an air conditioner;

FIGS. 5A and 5B are views illustrating an example of a change in heat generated in the racks and an accompanying change in the operating level of the underfloor fans, FIG. 5A illustrates an example of a change in the heat generation of the racks, and FIG. 5B illustrates an example of a change in the operating level of the underfloor fans accompanying the change in the heat generation of the racks;

FIG. 6 is a view illustrating an example of a change in the operating situation of a rack group illustrated in FIGS. 5A and 5B, and an example of a change in the highest intake temperature of a certain rack according to the change in the operating levels of the underfloor fans;

FIG. 7 is a view illustrating Table 1 that represents an average value of measured temperatures of 18 points of a region with a representation format for 4 operating levels of 2 underfloor fans;

FIG. 8 is a view illustrating Table 2 representing a distribution of measured temperatures in the measurement conditions (1) to (4);

FIG. 9 is a view illustrating Table 3 representing a distribution of predicted temperatures at unmeasured measurement points of FIG. 8 based on a correction parameter;

FIG. 10 is a graphical view illustrating the temperature distributions of FIG. 8 (Table 2) and FIG. 9 (Table 3) in the form of differences with a representative temperature;

FIGS. 11A and 11B are views illustrating measured values for entire conditions, FIG. 11A illustrates Table 4 representing the measured values and FIG. 11B illustrates a graph representing a distribution of measured values in the form of differences with the representative temperature; and

FIGS. 12A and 12B are views illustrating differences between the measured values illustrated in FIGS. 11A and 11B and the predicted values illustrated in FIGS. 9 and 10, FIG. 12A illustrates Table 5 representing the differences and FIG. 12B illustrates a graph representing a distribution of measured values in the form of differences with the representative temperature.

### DESCRIPTION OF EMBODIMENTS

Prior to description on an air conditioning management system according to an embodiment, a general air conditioning management system will be described.

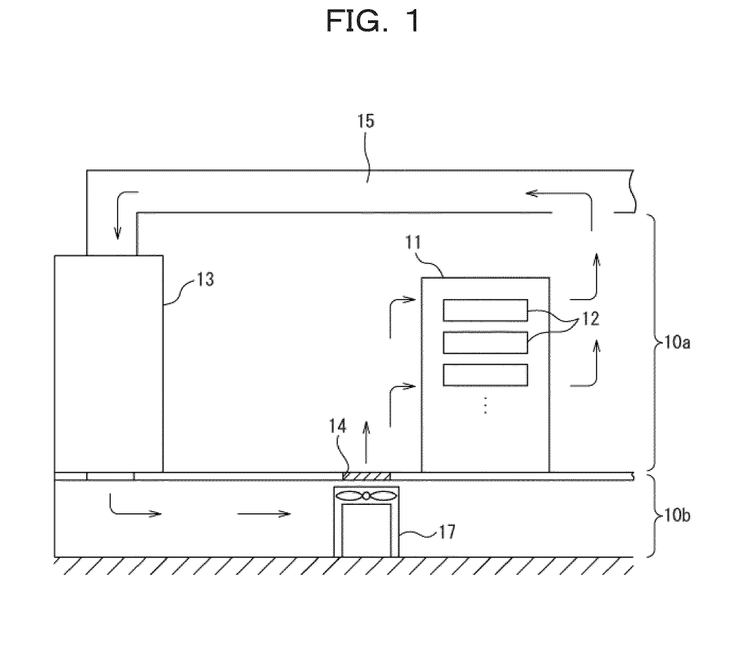

FIG. 1 is a view illustrating an exemplary configuration of an indoor air conditioning management system where the racks are installed accommodating electronic devices.

As illustrated in FIG. 1, a typical data center room is separated into an apparatus installation region 10a where racks 11 are installed, and a free access floor (underfloor space) 10b formed below the floor of the apparatus installation region 10a in order to arrange power cables and communication cables. Cold air is supplied from an air conditioner 13 into the free access floor 10b, and the cold air is sent to the apparatus installation region 10a via the grills (vent holes) installed in the floor of the apparatus installation region 10a. Typically, the cold air in the free access floor 10b is simply supplied into the apparatus installation region 10a via the grills 14 with an air blow pressure from the air conditioner 13. However, as will be described later, in some cases, an air blower 17 may be installed in the free access floor 10b under a particular grill 14 and the cold air from the air conditioner 13 may be more strongly supplied into the apparatus installation region 10a. The air conditioner 13 used herein may be sometimes called as a base air conditioner.

A number of racks 11 in which the electronic apparatuses (computers) 12 are accommodated are arranged side by side in each row. In a conventional rack, cold air is introduced from the front side of the rack to cool the computer, and the air with increased temperature is discharged through the rear side of the rack. The hot air discharged from the rack is returned to the air conditioner 13 via an exhaust duct 15 of upper side.

As described above, the front side of the rack is called an intake side and the rear side of the rack is called an exhaust side. In a conventional data center, a number of racks are lined up side by side in each row, the racks in adjacent rows are arranged in such a manner that intake sides or exhaust sides face with each other, and the grills are arranged in the floor of the intake sides. The region of a rack intake side into which the cold air is supplied is called a cold aisle and the region of a rack exhaust side from which the hot air is discharged is called a hot aisle.

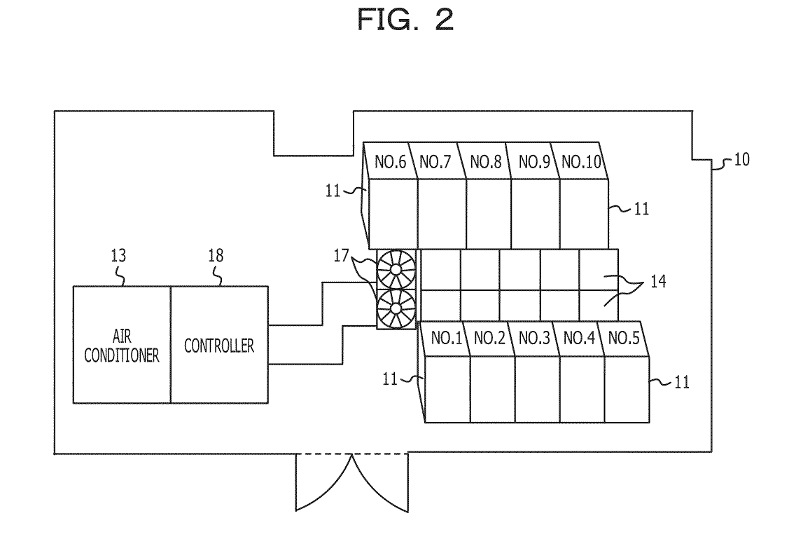

FIG. 2 is a view illustrating an example of arrangement of two rows of racks. As illustrated in FIG. 2, in a room 10, a first rack row where five racks 11 (No. 1 to No. 5) are arranged side by side and a second rack row where five racks 11 (No. 6 to No. 10) are arranged side by side are disposed in parallel. The region between the first rack row and the second rack row facing with each other corresponds to the cold aisle and the region of opposite sides of the first rack row and the second rack row corresponds to the hot aisle. A total of 12 grills 14 are installed in the floor of the cold aisle and two air blowers (underfloor fans) 17 are installed in the free access floor 10b under two grills 14 of a left side. A controller 18 is provided to control the temperature and the amount of air output by the air conditioner 13. The controller 18 also controls the operating level of the two underfloor fans 17. The underfloor fans are controlled, for example, with two operating levels of ON and OFF, or four operating levels of OFF, Weak, Middle and Strong. While the controller 18 is implemented by a computer system, but may be implemented with, for example, a sequencer.

As described above, a hot spot may occur and it is required to decrease the temperature to a predetermined value or less. By installing the underfloor fans 17 in the free access floor 10b, the cold air may be locally supplied to alleviate the hot spot. When the underfloor fans are installed under the grills of the intake side of each rack, the supply amount of the air may be minutely adjusted according to the temperature of the intake side of each rack. For example, a total of 12 underfloor fans are illustrated in the example of FIG. 2. In this case, however, the same number of underfloor fans as the racks is needed increasing the installation cost. In addition, as the number of underfloor fans increases, the power consumption increases accordingly as well. Therefore, there is a need to provide an air conditioning management system that cools the computers or other electronic apparatuses in the racks more efficiently with less number of underfloor fans than the racks.

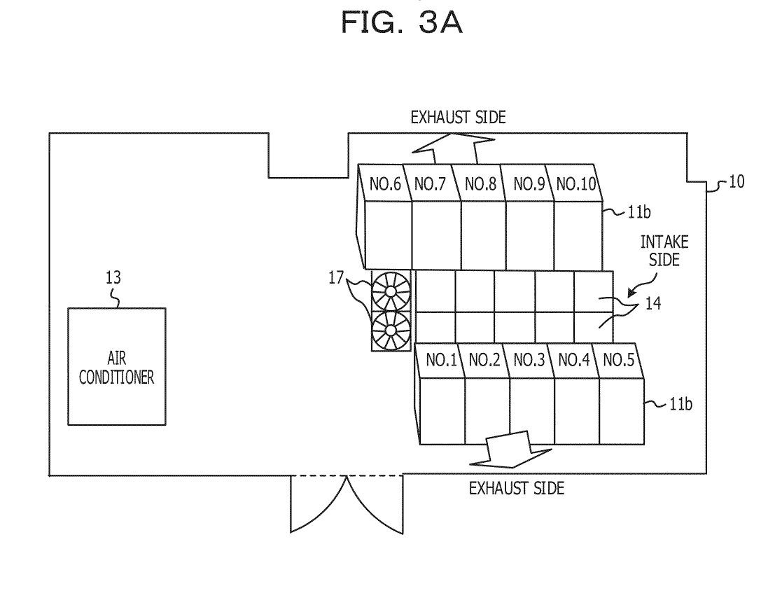

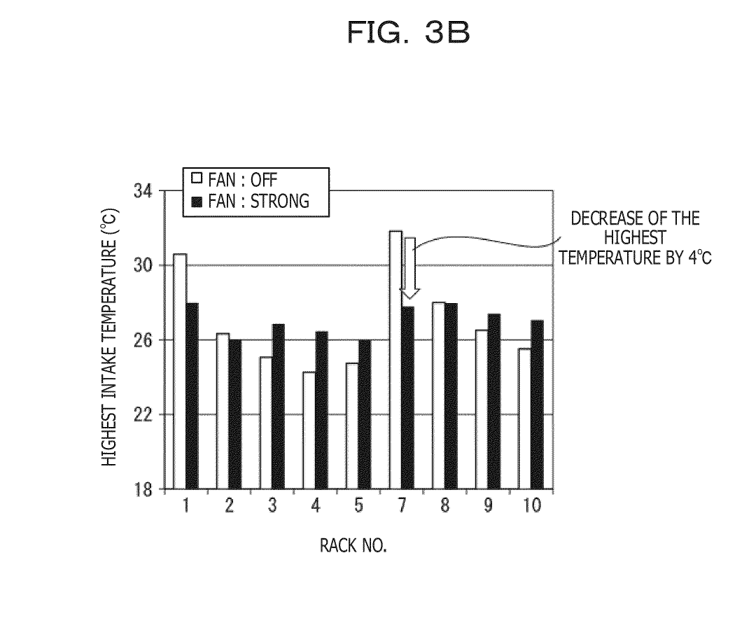

The air conditioning management system illustrated in FIG. 2 will now be described by way of an example. FIGS. 3A and 3B are views illustrating an air conditioning management system in which two underfloor fans are installed in a free access floor in a data center room 10 in which two rows of racks are installed, FIG. 3A illustrating the configuration and arrangement of the system and FIG. 3B illustrating a temperature change according to the operation of the underfloor fans.

In the system illustrated in FIG. 3A, a first rack row 11a including five racks 11 (No. 1 to No. 5) and a second rack row 11b including five racks 11 (No. 6 to No. 10) are arranged in parallel. A region between the first rack row 11a and the second rack row 11b facing with each other corresponds to the cold aisle, 12 grills 14 are installed in the floor, and two underfloor fans 17 are installed in the free access floor under the two left grills. A controller is not illustrated in the figure which will be the same herein below.

Temperature measuring devices (not illustrated) using an optical fiber are arranged in the intake side (cold aisle side) of the first rack row 11a and the second row 11b, and the controller 13 always measures the temperature of the entire region. These temperature measuring devices may precisely detect the temperature of the measurement points set at intervals of 10 cm to several 10 cm along the longitudinal direction of the optical fiber. The temperature is measured at several tens of (e.g., 50) measurement points of the intake side of a single rack 11, therefore, for example, the temperature of several hundreds of measurement points is measured for ten racks.

In the above-described temperature measuring devices, even though the two underfloor fans 17 are not installed, the temperature of the measurement points of the intake sides of all racks may be decreased to a predetermined temperature or less if the set temperature of the air conditioner 13 is lowered or the volume of air blow is increased in order to alleviate the hot spot. However, this control method may excessively cool the regions other than the hot spot, which may cause wasteful increase of air conditioning energy.

Accordingly, as illustrated in FIG. 3A, by appropriately blowing the cold air to the upper side with the two air blowers (underfloor fans) 17 installed under the two left grills 14, the hot spot may be alleviated.

As illustrated in FIG. 3B, when the underfloor fans 17 are turned OFF, the highest intake temperature of racks NO. 1 to NO. 7 exceeds a threshold temperature of 30° C. Particularly, the highest intake temperature of the rack NO. 7 is 32° C. Therefore, when the underfloor fans 17 are set to “Strong” among four operating levels of “OFF,” “Weak,” “Middle” and “Strong,” the highest intake temperature of the rack NO. 7 is decreased by 4° C. to 28° C. The highest intake temperature of the rack NO. 1 is decreased to 27° C. As a result, the measurement points whose highest intake temperature exceeds the threshold temperature of 30° C. are alleviated. In this state, it is unnecessary to lower the set temperature of the air conditioner 13 and no wasteful power is consumed.

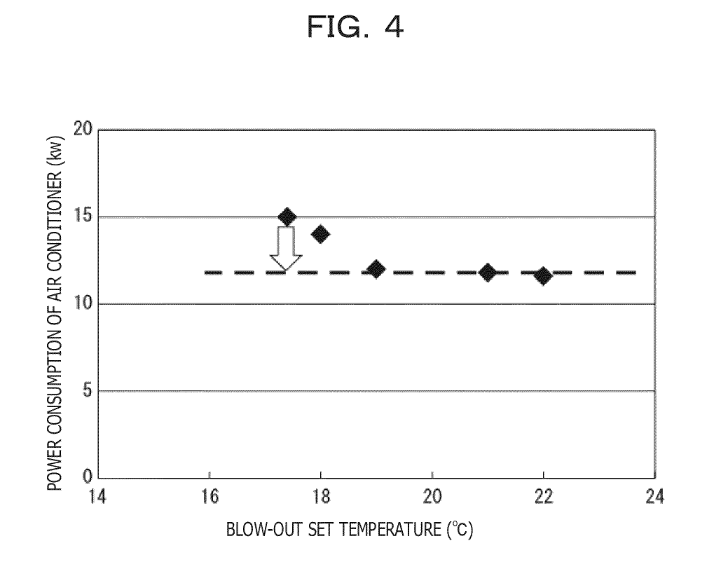

FIG. 4 is a view illustrating a relationship between blow-out set temperature and power consumption of an air conditioner.

For example, in the system of FIGS. 3A and 3B, when the hot spot is alleviated by lowering the blow-out set temperature of the air conditioner 13 with the underfloor fans 17 turned OFF, the blow-out set temperature has to be changed from 21° C. to 17° C. In contrast, when the underfloor fans 17 are set to the “Strong” operation, the hot spot may be alleviated with the blow-out set temperature remain to be set to 21° C.

As illustrated in FIG. 4, the power consumption of the air conditioner for the blow-out set temperature of 17° C. is 15.0 kW and the power consumption of the air conditioner for the blow-out set temperature of 21° C. is 11.8 kW. That is, the air conditioner power consumption is reduced by 3.2 kW by setting the underfloor fans 17 to the “Strong” operation. Since the power consumption of the underfloor fans 17 is small (e.g., 0.4 kW), power saving of 2.8 kW (=3.2 kW−0.4 kW), i.e., power saving of 19%, may be achieved as compared to a case when the set temperature of the air conditioner 13 is lowered.

With reference to FIG. 3B, considering the change in the temperature of each rack, the intake temperature of racks NO. 1 to NO. 7 near the underfloor fans is decreased by the operation of the underfloor fans, whereas the highest intake temperature of the racks NO. 3 to NO. 5, NO. 9, and NO. 10 remote from the underfloor fans is increased. This is because the total amount of cold air supplied from the air conditioner 13 is constant and, accordingly, the cold air in a certain region is decreased when the cold air in a specific region is increased by the operation of the underfloor fans 17. Since such a trade-off relationship is varied depending on the operation level of the underfloor fans (e.g., “OFF,” “Weak,” “Middle” and “Strong”), it is necessary to appropriately select the operation level of the underfloor fans so that the rack intake side may have a desirable temperature distribution. In addition, since the temperature distribution in the data center is changed due to the variation of the amount of the heat generated in the apparatuses such as servers, the operation level of the underfloor fans has to be accordingly changed from time to time.

However, in general, the conditions of airflow in the data center are too complicated to understand the above-described trade-off relationship in advance. Accordingly, in order to select a proper operating level of the underfloor fans, a proper condition has to be found by changing the operating level of the underfloor fans to some extent comprehensively.

An example of the change in the highest intake temperature of the racks when the operating level of the underfloor fans is changed along with the change in the heat generated in the racks will now be described.

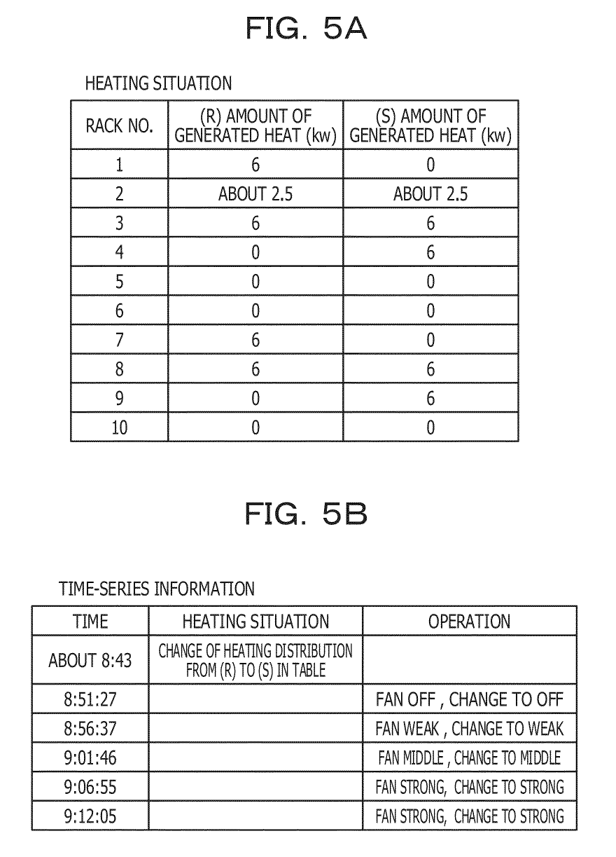

FIGS. 5A and 5B are views illustrating an example of a change in heat generated in the racks and an accompanying change in the operating level of the underfloor fans along with the change in heat generated in the racks, respectively.

As illustrated in FIG. 5A, the operating condition of the racks NO. 1 to NO. 10 is changed from a heating value (R) to a heating value (S). The heating values of the racks NO. 1 to NO. 10 are 6, about 2.5, 6, 0, 0, 0, 6, 6 and 0 kW for (R), respectively, and are about 2.5, 6, 6, 0, 0, 0, 6, 6 and 0 kW for (S), respectively.

As illustrated in FIG. 5B, when the two underfloor fans are both strongly operated into the normal state under the operating situation of a rack group of (R) in FIGS. 5A and 5B, the heating situation of the rack group has been changed at 8 o'clock 43 minutes (8:43) in time from (R) to (S) in FIG. 5A. Accordingly, the amount of heat generated in each rack is changed and the intake side temperature is slowly changed. Accordingly, the two underfloor fans have been sequentially changed to the same level. Specifically, the operating level of the two underfloor fans was “OFF” at 8:51:27, changed to “Middle” at 9:01:46, changed to “Strong” at 9:06:556m, and again changed to “Weak” at 9:12:05.

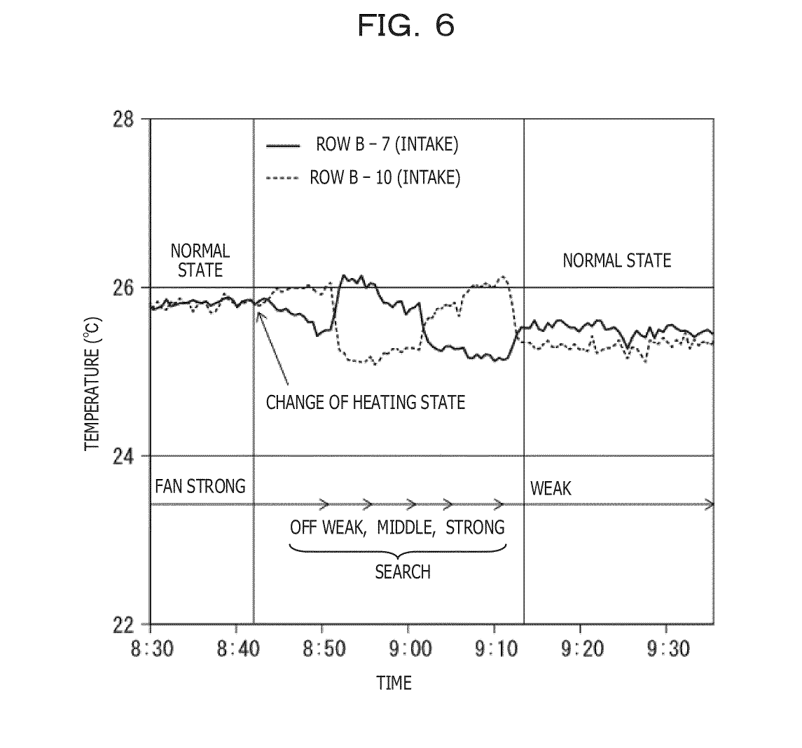

FIG. 6 is a view illustrating an example of a change in the operating situation of a rack group illustrated in FIGS. 5A and 5B, and an example of a change in the highest intake temperature of the racks NO. 7 and NO. 10 according to the change in the operating levels of the underfloor fans. As the heating situation of the rack group has been changed at 8:43 from (R) to (S), since the highest intake temperature of the rack NO. 7 is decreased and the highest intake temperature of the rack NO. 10 is increased, the operating level of the two underfloor fans has been changed to “OFF.” Thereafter, with lapse of some time, since the highest intake temperature of the rack NO. 7 is abruptly increased and the highest intake temperature of the rack NO. 10 is abruptly decreased, the operating level of the two underfloor fans has been sequentially changed from “Weak,” through “Middle,” to “Strong.” Thus, although the highest intake temperature of the rack NO. 7 is slowly decreased and further decreased when “Middle” and “Strong,” since the highest intake temperature of the rack NO. 10 is slowly increased and further decreased when “Middle” and “Strong,” the operating level has been changed to “Weak.” As a result, the two underfloor fans reached the normal state.

Although it is illustrated in FIGS. 5 and 6 that the operating levels of the two underfloor fans are simultaneously changed from “OFF,” through “Weak” and “Middle,” to “Strong” to find a condition (“Weak” in this case) for lowering the intake temperature as a whole, it takes about five minutes until the two underfloor fans reach the stable state in the respective conditions. In addition, only four conditions are provided since the two underfloor fans are operated with the same operating level. However, if the two underfloor fans are independently operated with four operating levels, a total of 16 (=4²) conditions may be employed. In addition, a total of 64 (=4³) conditions are taken for three underfloor fans and a total of 256 (=4⁴) conditions are taken for four underfloor fans, which makes the measurement for all the conditions impractical and results in difficulty in setting a proper fan operating condition.

In this way, when the plurality of underfloor fans each taking a number of operating levels is present, it is realistically difficult to measure and determine the entire conditions for an operating state of effectively lowering the rack intake side temperature.

A temperature distribution prediction method and an air conditioning management system according to an embodiment to be described below have the same basic configuration as the air conditioning management system illustrated in FIGS. 1 and 2 except that the controller 18 makes actual measurement for some conditions and makes a prediction for other conditions based on the measured values in the present embodiment. In addition, based on the measured values and the predicted values, the controller 18 controls the temperature of all regions to be a predetermined threshold temperature or less.

To begin with, the temperature of the rack intake sides is considered. It may be understood that the temperature of the rack intake sides is determined by a mixture of hot exhaust air and supplied cold air according to an equation which may be expressed as follows.

T_{rack}=δ*T_{c}+(1−δ)*Tₕ

where, T_{rack} is intake side temperature, T_{c} is supplied cold air temperature, Tₕ is hot exhausted air temperature, and δ is a mixture ratio of cold air.

For example, assuming that the hot exhausted air temperature is 30° C., the supplied cold air temperature is 20° C., and the mixture ratio is 0.2, the intake side temperature is 28° C. (=20*0.2+30*0.8). Taking the difference from Tₕ for both sides in the equation, the following equation may be obtained.

Tₕ−T_{rack}=δ(Tₕ−T_{c})

In this air conditioning management system, in the situation of lowering the rack intake side temperature by increasing the supplied cold air by operating the underfloor fans, it may be understood that the intake side temperature is changed as a result of the change in δ by the fan operation with the intake temperature before the fan operation set to Th.

Considering the fact that the intake side temperature is determined with the mixture of the cold air supplied into the intake sides, the effect by the operation of the plurality of underfloor fans may be understood as the superposition of effects by individual underfloor fans. Therefore, when the cold air mixture ratios δ by the operation of individual underfloor fans are known by measurement, the overall mixture ratio δ obtained when the plurality of underfloor fans is operated corresponds to the sum of these measured cold air mixture ratios. However, since the airflow in the data center is generally complicated, the overall mixture ratio δ may not often correspond to the simple sum. The mutual effect of the fans on the change in the airflow by the operation of the underfloor fans is determined from a positional relationship between the individual underfloor fans. In this embodiment, the intake temperature under conditions of non-measurement is predicted by introducing correction parameters for the mixture ratio and reflecting the mutual effect of the underfloor fans. For example, for two underfloor fans NO. 1 and NO. 2, assuming that cold air mixture ratios by the operation of the individual underfloor fans are δ₁ and δ₂, when correction parameters α₁ and α₂ are introduced to add the mutual effect of the underfloor fans, a difference is expressed by the following equation.

$$\begin{matrix}{T}_{h} - {T}_{rack} = {α}_{1} {δ}_{1} ( {T}_{h} - {T}_{c} ) + {α}_{2} {δ}_{2} ( {T}_{h} - {T}_{c} ) \\ = {α}_{1} ( {T}_{h} - T {1}_{rack} ) + {α}_{2} ( {T}_{h} - T {2}_{rack} )\end{matrix}$$

where, T1_{rack} and T2_{rack} represent the intake side temperature by the operation of the underfloor fans NO. 1 and NO. 2, respectively.

When the intake side temperature for each operating level of the individual underfloor fans and the correction parameters α₁ and α₂ are determined, the rack intake side temperature may be predicted even under the conditions of non-measurement.

In this embodiment, the intake side temperature under the following N operation conditions of the underfloor fans is measured, the correction parameters are calculated, and the intake side temperature under the conditions of non-measurement is predicted.
(1) Set the operating levels of all underfloor fans to the minimum.
(2) Set a specific operation condition where each operating level of all underfloor fans is any one of operating levels that may be employed.
(3) For each underfloor fan, set an operating condition in which an operating level is varied over (K−1) kinds from the particular operating condition, with the remaining (N−1) underfloor fans operating levels fixed.
(4) For each underfloor fan, set an operating condition in which other all operating levels of underfloor fans are set to the minimum.

The intake side temperature under the above conditions (1) to (4) is measured.

However, when the number of underfloor fans is 2 as described later, since the condition (4) is included in the condition (3) and accordingly the number of conditions for calculation of correction parameters is insufficient, an additional condition is measured.

Accordingly, when the number of underfloor fans is N and the number of operating levels of underfloor fans is K, the number of conditions to be measured is one for the condition (1), one for the condition (2), N*(K−1) for the condition (3), N for N≧3, and one for N=2. Accordingly, the total number of conditions is:

N*(K−1)+2+i (i is one for N=2 and N for N≧3).

For example, when the number of operating levels of the underfloor fans is 4 (K=4), the total number of operating conditions is K^{N}, there exist:
16 conditions for N=2,
64 conditions for N=3, and
256 conditions for N=4.

In contrast, in this embodiment, by the actual measurement of:
9 conditions for N=2,
16 conditions for N=3, and
18 conditions for N=4,
   the intake side temperature under other conditions of underfloor fans may be predicted.

According to the above-described method, the intake temperature of other conditions of non-measurement may be predicted based on the measured intake temperature of the smaller number of conditions. When a number of temperature sensors are installed, respective sensor values may be predicted and a fan operating condition taking the lowest value in the highest temperatures for the entire sensors may be selected.

The controller controls the predicted temperature for all regions to be the predetermined threshold temperature or less.

Hereinafter, a prediction method will be described by way of an example.
For N (the number of underfloor fans)=3 (fan a, fan b, and fan c) and K (the number of operating levels)=4

Here, the reason for K=4 is the assumption that one of the operating levels, “OFF,” “Weak,” “Middle” and “Strong,” may be selected for each underfloor fan.

The intake temperature for a certain fan operating level is represented by T_{abc}.

For the operating levels of underfloor fans, “OFF,” “Weak,” “Middle” and “Strong” are denoted by “0,” “1,” “2” and “3,” respectively. For example, T000 represents the intake temperature when the operating conditions for all fans a, b and c are 0 (OFF), and T213 represents the intake temperature when the operating conditions for the fans a, b and c are 2 (Middle), 1 (Weak) and 3 (Strong), respectively.

For example, the fans a, b and c are operated and the intake temperature is measured with the following conditions.
(1) Set the operating levels of all underfloor fans to the minimum. That is, measure T₀₀₀.
(2) Set a specific operation condition where each operating level of all underfloor fans is any one of operating levels that may be employed. For example, measure T₂₂₂. Hereinafter, it is assumed that T₂₂₂ is measured as a particular operating condition.
(3) For each underfloor fan, set an operating condition in which an operating level is varied over (K−1) kinds from the particular operating condition (2) (e.g., T₂₂₂), with the remaining (N−1) underfloor fans operating levels fixed. Accordingly, measure T₀₂₂, T₁₂₂, T₃₂₂, T₂₀₂, T₂₁₂, T₂₃₂, T₂₂₀, T₂₂₁ and T₂₂₃.
(4) For each underfloor fan, set an operating condition in which other all operating levels of underfloor fans are set to the minimum from the particular operating condition (2) (e.g., T₂₂₂). Accordingly, measure T₂₀₀, T₀₂₀ and T₀₀₂.

For the sake of simplicity, T′_{abc} is denoted as (T₀₀₀−T_{abc}). From the above measured values and correction parameters, the following equations may be obtained:

T′₂₂₂=α₁T′₂₀₀+α₂T′₀₂₀+α₃T′₀₀₂

T′₀₂₂=α₂T′₀₂₀+α₃T′₀₀₂

T′₂₀₂=α₁T′₂₀₀+α₃T′₀₀₂

T′₂₂₀=α₁T′₂₀₀+α₂T′₀₂₀.

The correction parameters α₁, α₂ and α₃ may be obtained using the least square method or the like.

Based on the obtained α₁, α₂ and α₃ and the measured values in the conditions (1), (2) and (4), T₁₀₀, T₃₀₀, T₀₁₀, T₀₃₀, T₀₀₁ and T₀₀₃ which are not measured may be predicted. For example, T₁₀₀ may be calculated from the equation of T′₁₂₂=α₁T′₁₀₀+α₂T′₀₂₀+α₃T′₀₀₂ (T′₁₂₂, T′₀₂₀ and T′₀₀₂ have been already measured). T₃₀₀, T₀₁₀, T₀₃₀, T₀₀₁ and T₀₀₃ may also be calculated in the same ways. By using the values obtained so far, the intake temperature for other all conditions under non-measurement may be predicted according to the following equation.

T′_{abc}=α₁T′ₐ₀₀+α₂T′_{0b0}+α₃T′₀₀c

In addition, for the above condition (2), any T_{abc} may be selected if a≠0, b≠0 and c≠0. The conditions of measurement with the above condition (2) are determined by the condition (2).

In addition, since the prediction is made based on the actual measured values near the condition (2) and the precision of prediction near the condition (2) is generally high, it is suitable to select the condition (2) based on conditions for which the intake temperature was low in the past.

Next, an example of a separate condition will be described.
For N (the number of underfloor fans)=2 (fan a and fan b) and K (the number of operating levels)=4

For example, the fans are operated and the intake temperature is measured with the following conditions.
(1) Set the operating levels of all underfloor fans to the minimum. That is, measure T₀₀.
(2) Set a specific operation condition where each operating level of all underfloor fans is any one of operating levels that may be taken. For example, measure T₂₂. Hereinafter, it is assumed that T₂₂ is measured as a particular operating condition.
(3) For each underfloor fan, set an operating condition in which an operating level is varied over (K−1) kinds from the particular operating condition (2) (e.g., T₂₂), with the additional underfloor fan operating level fixed. Accordingly, measure T₀₂, T₁₂, T₃₂, T₂₀, T₂₁ and T₂₃.
(4) For each underfloor fan, set an operating condition in which the operating level of the additional underfloor fan is set to the minimum from the particular operating condition (2) (e.g., T₂₂). Accordingly, measure T₀₂ and T₂₀.

For N=2, the condition (4) is included in the condition (3). For the sake of simplicity, T′ab is denoted as (T₀₀−T_{ab}).

Based the above measured values, the following equation may be obtained:

T′₂₂=α₁T′₂₀+α₂T′₀₂

However, another equation is required to calculate the correction parameters α₁ and α₂. Accordingly, a measured value for an appropriated condition is obtained. Here, T₀₁ for the condition (4) is obtained. Accordingly, an equation of T′₂₁=α₁T′₂₀+α₂T′₀₁ is obtained.

From the above two equations, α₁ and α₂ are calculated.

Based on the obtained α₁ and α₂ and the measured values in the conditions (1), (3) and (4), T₁₀, T₃₀ and T₀₃ which are not measured may be predicted. For example, T₁₀ may be calculated from the equation of

T′₁₂=α₁T′₁₀+α₂T′₀₂

Here, T′₁₂ and T′₀₂ have been already measured. Accordingly, T₁₀ may be calculated from the above equation. T₃₀ and T₀₃ may also be calculated in the same ways. By using the values obtained so far, the intake temperature for other all conditions under non-measurement may be predicted according to the following equation.

T′_{ab}=α₁T′ₐ₀+α₂T′_{0b}

Hereinafter, a specific example of the measurement will be described.

An example of measurement in the air conditioning management system illustrated in FIG. 3A will be described. In the room configuration of FIG. 3A, the intake temperature was measured using the optical fiber temperature sensors attached to the intake side of the rack NO. 1. The object of the measurement is one region (area) of the four-divided rack intake side. The number of measurement points in one region is 18.

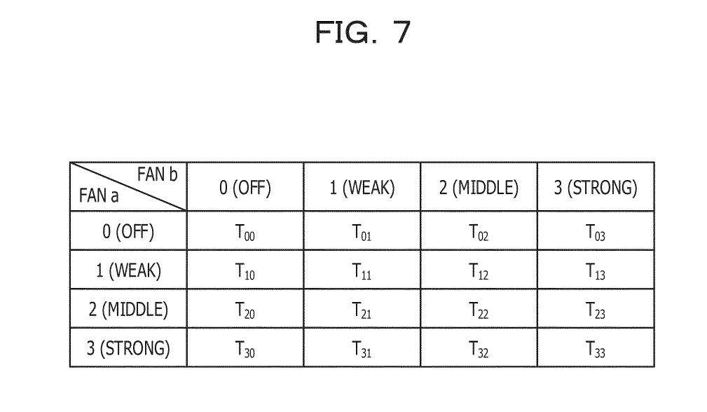

FIG. 7 is a view illustrating Table 1 in which the averages values of temperatures measured at the 18 points in the region are represented for four operating levels of the underfloor fans a and b.

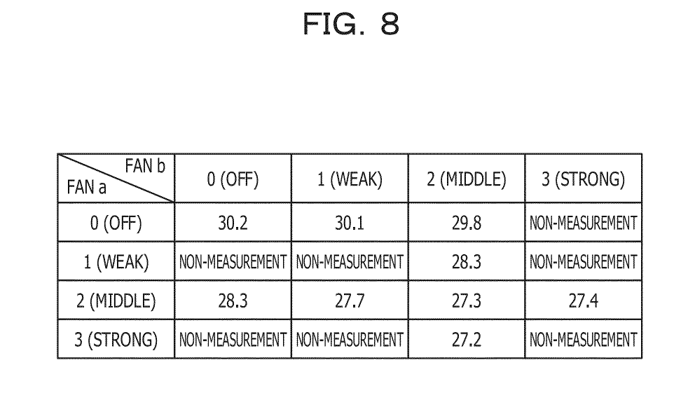

FIG. 8 is a view illustrating Table 2 representing a distribution of measured temperatures in the above-described measurement conditions (1) to (4). In the table, “non-measurement” indicates that no temperature is measured in the measurement conditions (1) to (4).

The correction parameters α₁ and α₂ obtained from the temperature distribution of FIG. 8 according to the above-described sequence was 1.37 and 0.499, respectively.

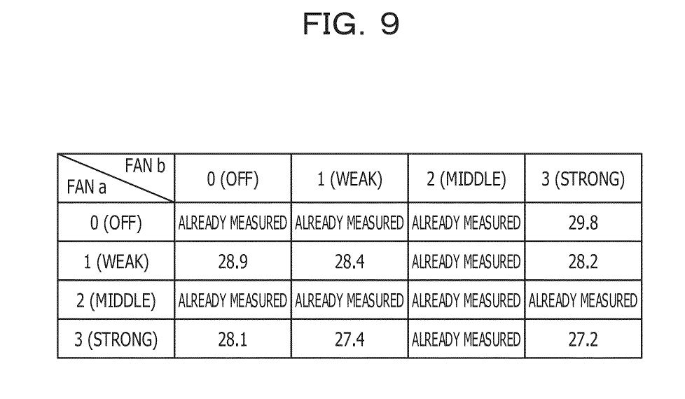

FIG. 9 is a view illustrating Table 3 representing a distribution of predicted temperatures at measurement points of non-measurement of FIG. 8 based on the correction parameters α₁ and α₂.

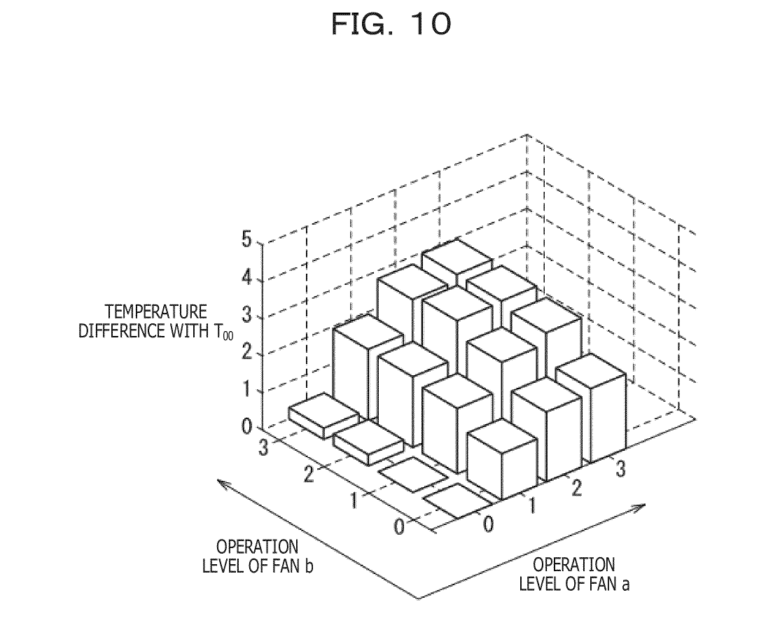

FIG. 10 is a graphical view illustrating the temperature distributions of FIG. 8 (Table 2) and FIG. 9 (Table 3) in the form of differences with a representative temperature T₀₀.

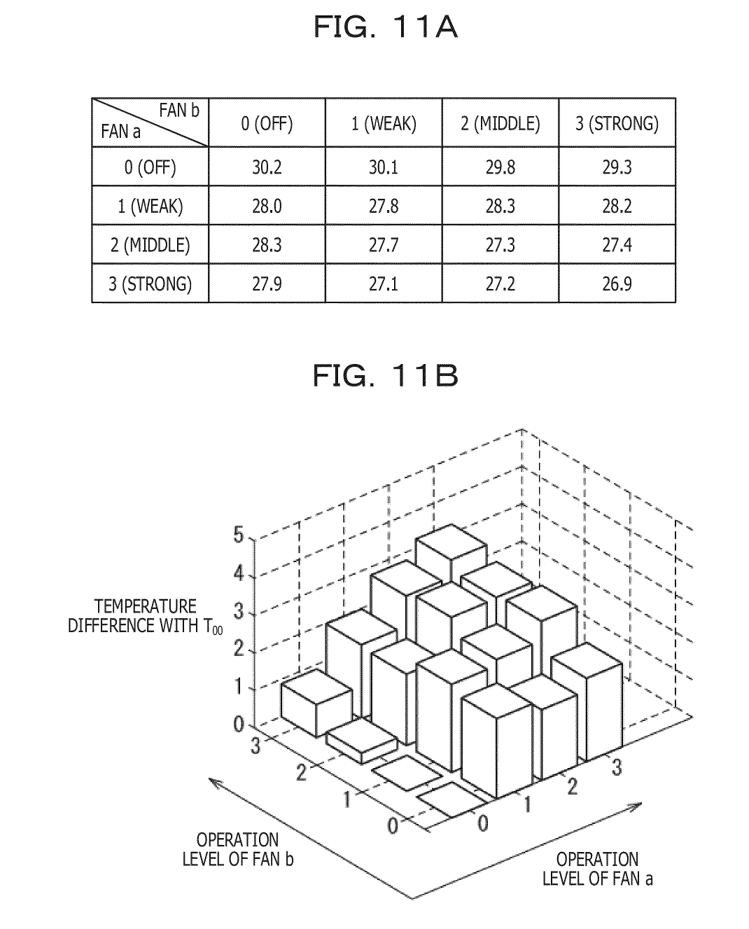

FIGS. 11A and 11B are views illustrating measured values for the overall conditions, FIG. 11A illustrating Table 4 representing the measured values and FIG. 11B illustrating a graph representing a distribution of measured values in the form of differences with T₀₀.

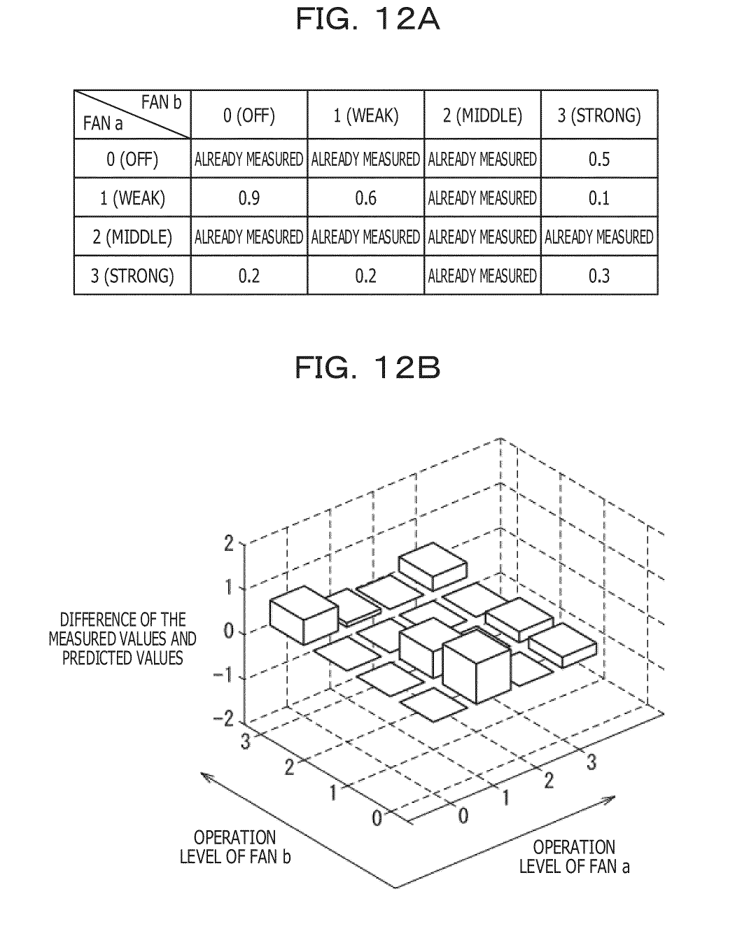

FIGS. 12A and 12B are views illustrating differences between the measured values illustrated in FIGS. 11A and 11B and the predicted values illustrated in FIGS. 9 and 10, FIG. 12A illustrating Table 5 representing the differences and FIG. 12B illustrating a graph representing a distribution of measured values in the form of differences with T₀₀. It may be seen from the result of FIGS. 12A and 12B that the differences between the predicted values and the measured values are so small as to provide an effective prediction.

Although one region (area) of the four-divided rack intake side of NO. 1 has been illustrated in the above measurement example, in reality, the intake temperature of non-measurement for other regions are predicted by calculating the correction parameters α1 and α2 in the same ways. Hereinafter, a process of obtaining predicted values for the overall region will be described by ways of an example of the air conditioning management system illustrated in FIG. 3A.

For this system, the N (the number of underfloor fans) is 2 (fan a and fan b) and K (the number of operating levels) is 4. As illustrated in FIG. 3A, a total of 40 areas are considered when the number of racks is 10 and one rack is divided in four 4 areas. The number of measurement points of one area is 18 and the total number of measurement points is 720.
1. According to the above-described calculation method, (α1(AreaNo.), (α2(AreaNo.)) are calculated for each of the 40 areas. That is, (α1(1), α2(1)), (α1(2), α2(2)), . . . , (α1(40), α2(40)) are calculated.
2. (α1(AreaNo.), (α2(AreaNo.)) are used to obtain Txy(AreaNo.) for each of the 40 areas under the fan conditions of non-measurement. Accordingly, T_{xy}(AreaNo.) of the 16 fan conditions (two underfloor fans of four operating levels) for each of the 40 areas matching the already measured conditions are obtained as follows.

T₀₀(1), T₀₁(1), T₀₂(1), . . . , T₃₃(1),

T₀₀(2), T₀₁(2), T₀₂(2), . . . , T₃₃(2),

T₀₀(40), T₀₁(40), T₀₂(40), . . . , T₃₃(40)
3. The highest temperature for each of the fan conditions is extracted. Here, MAX( ) represents the highest value in ( )

MAX_{—}T₀₀=MAX(T₀₀(1), T₀₀(2), . . . , T₀₀(40)),

MAX_{—}T₀₁=MAX(T₀₁(1), T₀₁(2), . . . , T₀₁(40)),

MAX_{—}T₃₃=MAX(T₃₃(1), T₃₃(2), . . . , T₃₃(40))
4. A fan condition representing the lowest one of the obtained highest temperatures for the 16 fan conditions is selected. Here, MIN( ) represents the lowest value in ( ).

A fan condition of MIN_MAX_T_{xy} is selected from MIN_MAX_T_{xy}=MIN(MAX_T₀₀, MAX_T₀₁, . . . , MAX_T₃₃).

When the operating conditions of the underfloor fans are varied based on the predicted values and new measured values are obtained, the new measured values are used to update the correction parameters using, for example, the least square method to improve the precision of prediction.

In this embodiment, the same correction parameters have been applied with the overall conditions of the fan operating levels as one area with T₀₀ as a base. When there are more fans, the prediction may be more likely to be significantly incorrect when the same correction parameters are applied with the overall conditions of the fan operating levels. The precision of prediction may be improved when the one area is divided into areas having similar operating conditions and the correction parameters are introduced for each area. In this case, the temperature serving as the base is not limited to T₀₀ but may be an intake temperature for an appropriate condition nearby.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a illustrating of the superiority and inferiority of the invention. Although the embodiments of the present invention have been described in detail, it should be understood that the various changes, substitutions, and alterations could be made hereto without departing from the spirit and scope of the invention.

What is claimed is:

1. A temperature distribution prediction method of predicting a predetermined temperature distribution in an air conditioning system, the air conditioning system including an air conditioner for supplying temperature-adjusted air into a room where racks in which electronic apparatuses are accommodated are installed; and air blowers for transferring the air supplied from the air conditioner to an intake side of the racks, the method comprising:
measuring the temperature distribution for actual conditions varying the operating situations of the air blowers; and
predicting the temperature distribution for conditions of non-measurement for the air blowers based on the measured values.

2. The temperature distribution prediction method according to claim 1, wherein, when the number of operating levels of the air blowers is K and the number N of air blowers is 2, the temperature distribution is measured under (2×(K−1)+3) conditions including:
an operating condition where operating levels of two air blowers are set to the minimum;
a particular operating condition where each of the operating levels of the two air blowers is set to any one of operating levels that may be employed;
an operating condition where the operating level for each of the air blowers is varied with (K−1) kinds from the particular operating condition, with other air blower operating levels fixed; and
other operating conditions where the operating level of one air blower is set to the minimum from the particular operating condition, and
the temperature distribution for other operating conditions is predicted based on the measured temperature distribution.

3. The temperature distribution prediction method according to claim 1, wherein, when the number of operating levels of the air blowers is K and the number N of air blowers is 3 or more, the temperature distribution is measured under (N×K+2) conditions including:
an operating condition where operating levels of all of the air blowers are set to the minimum;
a particular operating condition where each of the operating levels of all of the air blowers is set to any one of operating levels that may be employed;
an operating condition where the operating level for each of the air blowers is varied with (K−1) kinds from the particular operating condition, with the remaining (N−1) air blower operating levels fixed; and
other operating conditions where the operating levels of other all air blowers are set to the minimum from the particular operating condition, and the temperature distribution for other operating conditions is predicted based on the measured temperature distribution.

4. An air conditioning management system comprising:
a temperature distribution measuring unit configured to measure a temperature distribution of a predetermined region in a room where racks in which electronic apparatuses are accommodated are installed;
an air conditioner configured to supply temperature-adjusted air into the room;
air blowers each configured to transfer the air supplied from the air conditioner to an intake side of the racks; and
a controller configured to control the operating state of the air blowers based on the temperature distribution measured by the temperature distribution measuring unit,
wherein the controller predicts the temperature distribution for conditions of non-measurement for the air blowers based on measured values of the temperature distribution for actual conditions varying the operating situation of the air blowers, and operates the air blowers under the optimal operating state based on a result of the prediction.

5. The air conditioning management system according to claim 4, wherein, when the number of operating levels of the air blowers is K and the number N of air blowers is 2, the temperature distribution is measured under (2×(K−1)+3) conditions including:
an operating condition where operating levels of two air blowers are set to the minimum;
a particular operating condition where each of the operating levels of the two air blowers is set to any one of operating levels that nay be employed;
an operating condition where the operating level for each of the air blowers is varied with (K−1) kinds from the particular operating condition, with other air blower operating levels fixed; and
other operating conditions where the operating level of one air blower is set to the minimum from the particular operating condition, and
the temperature distribution for other operating conditions is predicted based on the measured temperature distribution.

6. The air conditioning management system according to claim 4, wherein, when the number of operating levels of the air blowers is K and the number N of air blowers is 3 or more, the temperature distribution is measured under (N×K+2) conditions including:
an operating condition where operating levels of all of the air blowers are set to the minimum;
a particular operating condition where each of the operating levels of all of the air blowers is set to any one of operating levels that may be employed;
an operating condition where the operating level for each of the air blowers is varied with (K−1) kinds from the particular operating condition, with the remaining (N−1) air blower operating levels fixed; and
other operating conditions where the operating levels of other all air blowers are set to the minimum from the particular operating condition, and
the temperature distribution for other operating conditions is predicted based on the measured temperature distribution.

7. The air conditioning management system according to claim 4, wherein the temperature distribution measuring unit includes an optical fiber sensor.
